(19) United States
(12) Patent Application Publication
(10) Pub. No.: US 2015/0187728 A1
(43) Pub. Date: Jul. 2, 2015

(54) EMICONDUCTOR DEVICE WITH DIE TOP POWER CONNECTIONS

(71) Applicants: Kesvakumar V.C. Muniandy, Klang (MY); Navas Khan Oratti Kalandar, Pelaling Jaya (MY); Lan Chu Tan, Singapore (SG)

(72) Inventors: Kesvakumar V.C. Muniandy, Klang (MY); Navas Khan Oratti Kalandar, Pelaling Jaya (MY); Lan Chu Tan, Singapore (SG)

(21) Appl. No.: 14/141,465

(22) Filed: Dec. 27, 2013

(51) Int. Cl. H01L 23/00

(52) U.S. Cl. CPC H01L 24/85; H01L 24/49; H01L 24/09; H01L 24/03; H01L 2224/031; H01L 2224/49431; H01L 2224/48096; H01L 2224/48108; H01L 2224/49175; H01L 2224/04042

(57) ABSTRACT

In a packaged semiconductor device, a die is mounted on a substrate having power connection pads. An exterior (e.g., top) surface of the die has power bond pads and distributed power feed pads. Bond wires electrically connect the power connection pads of the substrate to the power bond pads of the die, and exterior conductive structures electrically connect the power bond pads of the die to the distributed power feed pads of the die. The exterior conductive structures are printed or pasted onto the exterior die surface. Using exterior conductive structures instead of interior conductive traces (in the die) reduces resistive power losses and frees up more room for routing signals within the interior die layers.

### BACKGROUND OF THE INVENTION

The present invention relates generally to integrated circuit packaging, and more particularly to power connections for semiconductor devices.

According to some conventional designs for semiconductor devices an integrated circuit (IC) die is mounted on a substrate and bond wires are used to electrically connect connection pads on the substrate with bond pads located around the periphery of the top (active) surface of the die. Some of the electrical connections are for transmitting signals to and from the die, while others are for providing power to the die in the form of power supply and ground voltages.

In a conventional packaged semiconductor device, a wire bond power connection (i.e., either power supply or ground) involves a bond wire connecting a power connection pad on the substrate to a power bond pad on the periphery of the top surface of the die. The power is then routed horizontally and/or vertically into the die using metal traces within the die's bond pad layer and/or metal vias to one or more locations in the die where that power is needed.

In order to keep IC dies as small as possible, die layers are kept as thin as possible, and the area of the die layers is kept as small as possible. As a result, the resistances of the conductive traces used to propagate power within the die layers are relatively high, resulting in relatively high resistive power losses. Thus, it would be advantageous to have another way to route power to various locations in an IC die.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIGS. 1(A) and 1(B) show simplified side and top plan views, respectively, of portion of a semiconductor device according to one embodiment of the invention; and

FIG. 2 shows a side view of a process of printing exterior conductive structures onto the top of an IC die such as that used in FIG. 1, according to one embodiment of the invention.

### DETAILED DESCRIPTION OF THE INVENTION

Detailed illustrative embodiments of the present invention are disclosed herein. However, specific structural and functional details disclosed herein are merely representative for purposes of describing example embodiments of the present invention. The present invention may be embodied in many alternate forms and should not be construed as limited to only the embodiments set forth herein. Further, the terminology used herein is for the purpose of describing particular embodiments only and is not intended to be limiting of example embodiments of the invention.

As used herein, the singular forms “a,” “an,” and “the,” are intended to include the plural forms as well, unless the context clearly indicates otherwise. It further will be understood that the terms “comprises,” “comprising,” “includes,” and/or “including,” specify the presence of stated features, steps, or components, but do not preclude the presence or addition of one or more other features, steps, or components. It also should be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In one embodiment, the present invention provides a packaged semiconductor device comprising (i) a substrate having power connection pads, (ii) a die mounted on the substrate and having power bond pads and distributed power feed pads on an exterior surface thereof, (iii) a first bond wire electrically connecting a first power connection pad of the substrate to a first power bond pad of the die, and (iv) a first exterior conductive structure electrically connecting the first power bond pad of the die to a first distributed power feed pad of the die, wherein the first exterior conductive structure is not a bond wire.

In another embodiment, the present invention is a method of assembling a packaged semiconductor device and a packaged semiconductor device assembled using that method. The method comprises (a) mounting a die on a substrate, where the substrate has power connection pads, and the die has power bond pads and distributed power feed pads on its exterior surface; (b) forming exterior conductive structures on the exterior surface of the die that electrically connect the power bond pads of the die to the distributed power feed pads of the die, where the exterior conductive structures are not bond wires; and (c) electrically connecting a first power connection pad of the substrate and one of the power bond pads of the die with a bond wire to form an electrical connection between the first power connection pad of the substrate and the first distributed power feed pad of the die.

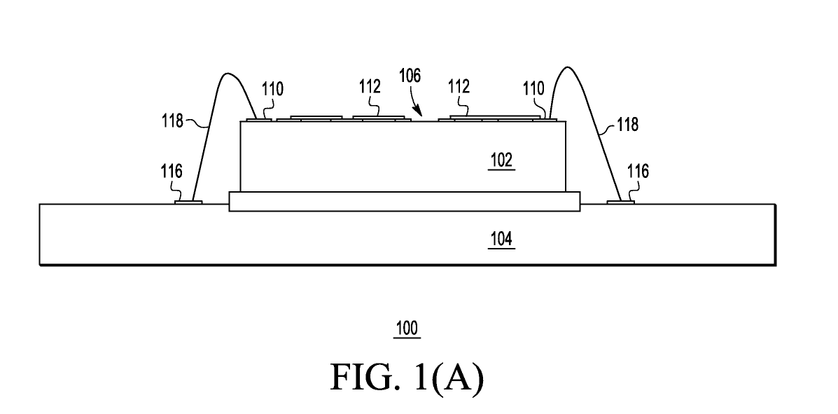

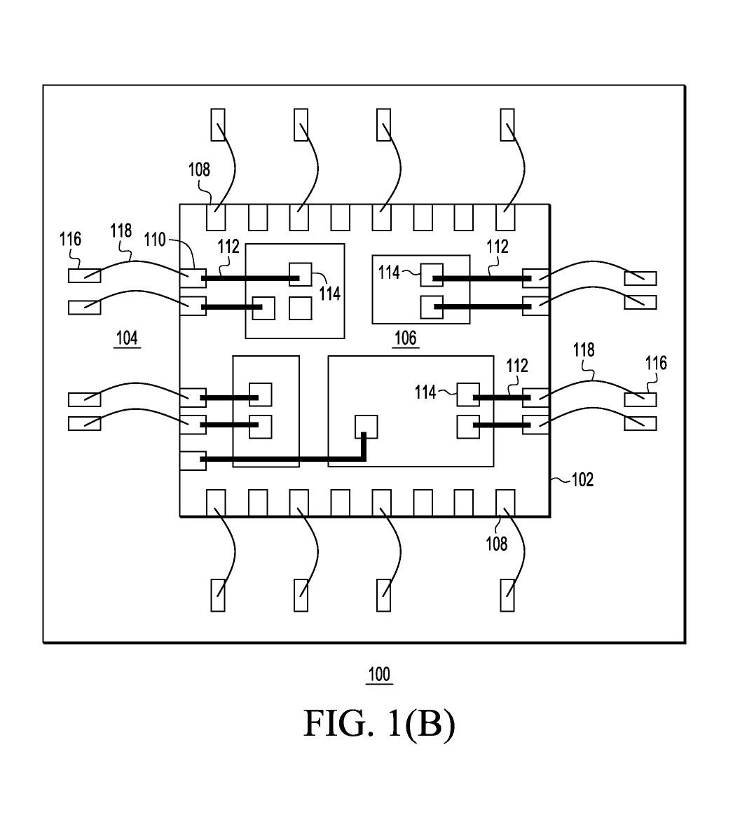

FIGS. 1(A) and 1(B) show simplified side and top plan views, respectively, of a portion of a packaged semiconductor device 100 having an IC die 102 attached to a substrate 104, according to one embodiment of the invention. As shown in FIG. 1(B), the die 102 has a number of bond pads located around the periphery of its top or active surface 106. In this exemplary embodiment and in the orientation presented in FIG. 1(B), the bond pads located at the top and bottom sides of the die 102 are signal bond pads 108 for transmitting signals to and from the die 102, while the bond pads located at the left and right sides of the die 102 are power bond pads 110 for providing power supply and ground voltages to the die 102. In other embodiments, there are bond pads located on all four sides of the die 102. Of course, it will be understood by those of skill in the art that the power bond pads may be disposed along all four sides of the die, as may be the signal bond pads, and the signal and power bond pads may be interleaved amongst each other.

Instead of routing power from the power bond pads 110 first vertically (with vias) and then horizontally with metal routing layers) within the die, as is done in the prior art, in the embodiment of FIG. 1, power is initially routed on the exterior of the die 102 with conductive structures 112 formed on the top surface 106 of the die 102. The conductive structures 112 extend from the peripheral power bond pads 110 to distributed power feed pads 114 located away from the periphery of the die 102 and above the locations within the interior of the die 102 where power is needed. Note that the conductive structures 112 include at least one conductive structure that is not a bond wire. Vias are then provided that route the power down to the one or more particular die layers where it is needed.

Thus, power is provided to die 102 from power connection pads 116 on the substrate 104 through bond wires 118 to the power bond pads 110 on the periphery of the top surface 106 of the die 102, and then from the power bond pads 110 through the exterior conductive structures 112 to the distributed power feed pads 114 on the top surface 106 of the die 102, and then from the distributed power feed pads 114 through corresponding vertical vias (not shown) to locations (also not shown) within the interior of the die 102.

Because the exterior conductive structures 112 are formed on the top surface 106 of the die 102, there is little constraint on the height of the conductive structures 112. Furthermore, since no other signals are being routed on the top surface 106 of the die 102, the exterior conductive structures 112 can be wider than the interior traces located within IC layers of the die 102. Further, the exterior conductive structures 112 may even be thicker than presently done using internal tracks on the metal layers within a die. As such, the exterior conductive structures 112 can be made to have significantly less resistance than if the power signals were routed using conventional metal routing lines within the die. As a result, the power losses for packaged semiconductor devices of the invention can be significantly lower than power losses for comparable devices of the prior art.

Furthermore, since fewer conductive traces are needed in the interior IC layers for transmitting power, there is more room available within those interior IC layers for routing signals, which may even result in comparable dies having fewer IC layers.

There are different ways to the implement exterior conductive structures 112. According to certain embodiments, the exterior conductive structures 112 are printed onto the top surface 106 of the die 102 using stencil printing or pen writing. According to other embodiments, the exterior conductive structures 112 are applied onto the top surface 106 of the die using plating techniques.

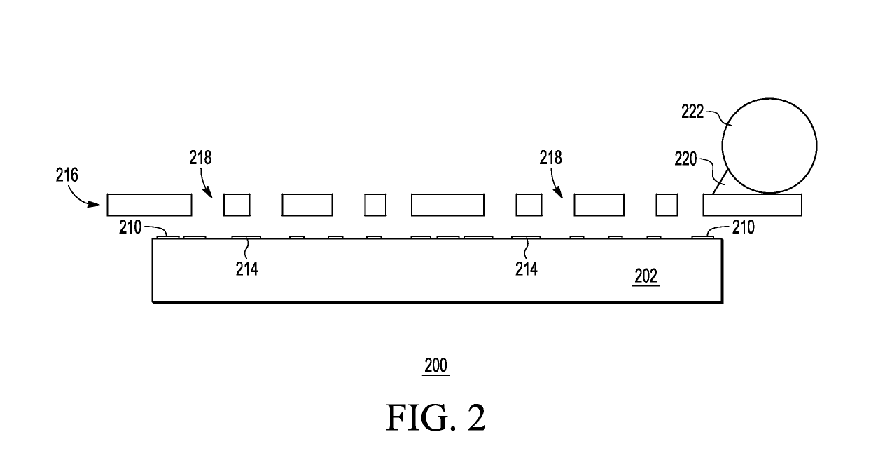

FIG. 2 shows a side view of a process of printing exterior conductive structures onto the top of an IC die 202, according to one embodiment of the present invention. As represented in FIG. 2, the die 202 has bond pads 210 and distributed power feed pads 214 formed on its top surface. As can be seen, the bond pads 210 are located along a periphery of the die 202 while the power feed pads 214 are more central or spaced from the periphery. A stencil 216 having openings 218 corresponding to the locations and shapes of the various (eventual) exterior conductive structures, is positioned over the top of the die 102, and a suitable conductive material (e.g., conductive epoxy or other suitable conductive paste or liquid) 220 is rolled over the stencil 216 using a suitable squeegee 222 or other tool to force the conductive material to fill the stencil openings 218. The stencil 216 can then be removed and the conductive material suitably cured to form the exterior conductive structures connecting peripheral power bond pads 210 to interior distributed power feed pads 214. Standard processing may be applied for the other steps involved in the assembly of the resulting packaged semiconductor device.

By now it should be appreciated that there has been provided an improved packaged semiconductor device and a method of forming the packaged semiconductor device. Circuit details are not disclosed because knowledge thereof is not required for a complete understanding of the invention.

Although the invention has been described using relative terms such as “upper,” “lower,” “front,” “back,” “top,” “bottom,” “over,” “under” and the like in the description and in the claims, such terms are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Unless stated otherwise, terms such as “first” and “second” are used to arbitrarily distinguish between the elements such terms describe. Thus, these terms are not necessarily intended to indicate temporal or other prioritization of such elements. Further, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

1. A semiconductor device, comprising:
a substrate having power connection pads;
a die mounted on the substrate and having power bond pads and distributed power feed pads on an exterior surface of the die;
a first bond wire electrically connecting a first power connection pad of the substrate to a first power bond pad of the die; and
a first exterior conductive structure electrically connecting the first power bond pad of the die to a first distributed power feed pad of the die, wherein the first exterior conductive structure is not a bond wire.

2. The semiconductor device of claim 1, wherein:
the first power bond pad of the die is located at the periphery of the exterior surface of the die; and
the first distributed power feed pad of the die is located away from the periphery of the exterior surface of the die.

3. The semiconductor device of claim 1, wherein the first exterior conductive structure comprises a conductive element printed onto the exterior surface of the die.

4. The semiconductor device of claim 3, wherein the conductive element is printed onto the exterior surface of the die using stencil printing.

5. The semiconductor device of claim 3, wherein the conductive element is printed onto the exterior surface of the die using pen writing.

6. The semiconductor device of claim 1, wherein the first exterior conductive structure comprises a conductive element that is pasted onto the exterior surface of the die.

7. The semiconductor device of claim 1, further comprising:
one or more other bond wires connecting one or more other power connection pads of the substrate to one or more other power bond pads of the die; and
one or more other exterior conductive structures connecting the one or more other power bond pads of the die to one or more other distributed power feed pads of the die.

8. The semiconductor device of claim 7, wherein the one or more other exterior conductive structures each is printed onto the exterior surface of the die.

9. The device of claim 7, wherein the one or more other exterior conductive structures each are pasted onto the exterior surface of the die.

10. A method of assembling a semiconductor device, the method comprising:
(a) mounting a semiconductor die on a substrate, wherein the substrate has power connection pads and the die has power bond pads and distributed power feed pads on an exterior surface of the die;
(b) forming exterior conductive structures on the exterior surface of the die, wherein the exterior conductive structures comprise a first exterior conductive structure electrically connecting a first power bond pad of the die to a first distributed power feed pad of the die, wherein the first exterior conductive structure is not a bond wire; and
(c) wire bonding a first bond wire between (i) a first power connection pad of the substrate and (ii) the first power bond pad of the die to form an electrical connection from the first power connection pad of the substrate and the first distributed power feed pad of the die.

11. The method of claim 10, wherein step (b) comprises:
(b1) applying a stencil to the exterior surface of the die, the stencil having openings corresponding to the exterior conductive structures of the semiconductor device;
(b2) applying a conductive material onto the stencil and into the openings of the stencil; and
(b3) removing the stencil and curing the conductive material to form the exterior conductive structures on the exterior surface of the die.

12. The method of claim 10, wherein the exterior conductive structures are formed using pen writing.

13. The method of claim 10, wherein the exterior conductive structures are formed using a printing technique.

14. A packaged semiconductor device formed using the method of claim 10.
